(19) United States
(12) Patent Application Publication
(10) Pub. No.: US 2009/0160981 A1
(43) Pub. Date: Jun. 25, 2009

(54) APPARATUS INCLUDING GREEN AND MAGENTA PIXELS AND METHOD THEREOF

(75) Inventors: Richard Albert Baumgartner, Palo Alto, CA (US); Charles E. Moore, Loveland, CO (US); Akihiro Machida, Sunnyvale, CA (US)

Correspondence Address: RatnerPrestia, P.O. BOX 980, VALLEY FORGE, PA, 19482, US

(73) Assignee: MICRON TECHNOLOGY, INC., Boise, ID (US)

(21) Appl. No.: 11/961,208

(22) Filed: Dec. 20, 2007

(51) Int. Cl. H04N 5/335; H01L 27/146

(52) U.S. Cl. 348/274; 257/292; 257/E27.133; 348/E05.091

(57) ABSTRACT

A color photo sensing structure, includes an array of multiple color photo sensing elements. The photo sensing structure includes a first pixel located laterally with respect to a second pixel in a substrate of a first conductivity. The first pixel includes a first doped region of a second conductivity formed in the substrate and a second doped region of a first conductivity formed in the substrate above the first doped region. The second pixel includes two doped regions formed in the substrate having a first conductivity and a second conductivity, respectively. The color photo sensing structure further includes a controller for sequentially providing a first photocurrent value of the first doped region, a second photocurrent value of both the first and second doped regions and a third photocurrent value of the two doped regions of the second pixel.

### BACKGROUND OF THE INVENTION

Imagers, including complimentary metal oxide semiconductor (CMOS) imagers and charge-coupled devices (CCD), may be used in digital imaging applications to capture scenes. An imager includes an array of pixels. Each pixel in the array includes at least a photosensitive element for outputting a signal having a magnitude proportional to the intensity of incident light contacting the photosensitive element. When exposed to incident light to capture a scene, each pixel in the array outputs a signal having a magnitude corresponding to an intensity of light at one point in the scene. The signals output from each photosensitive element may be processed to form an image representing the captured scene.

To capture color images, the photo sensors should be able to separately detect photons of wavelengths of light associated with different colors. For example, a photo sensor may be designed to detect first, second, and third colors (e.g., red, green and blue photons.) In one imager design, each pixel cell may be sensitive to only one color or spectral band. For this, a color filter array may be placed over each pixel cell so that each pixel cell ideally measures only wavelengths of the color of the pixel's associated filter. A group of four pixels (2 green, 1 red and 1 blue) are typically used to capture three different colors of incident light. The groups of four may be repeated throughout an imager array to form an array of many rows and columns.

In another imager design, one pixel may measure all three colors. This design takes advantage of the absorption properties of semiconductor materials. That is, in a typical semiconductor substrate, different wavelengths of light are absorbed at different depths in the substrate. For example, blue light is absorbed in a silicon substrate primarily at a depth of about 0.2 to 0.5 microns, green light is absorbed in a silicon substrate primarily at a depth of about 0.5 to 1.5 microns and red light is absorbed in the silicon substrate at a depth of about 1.5 to 3.0 microns.

This pixel structure includes three stacked pixels formed from two levels of N diffusions and a P well that are diffused in a silicon substrate. This results in a structure having three p-n junctions forming three photodiodes at different depths in the substrate, each designed to primarily absorb a particular color of incident light. Typically, the blue photodiode will be closest to the incident light, the red photodiode will be farthest from the incident light and the green photodiode will be between the blue and red junctions, due to the absorption properties described above. In this way, only one vertically stacked pixel is needed to absorb three or more different colors of light.

In operation, however, the spectral characteristics of the three colors in the vertically stacked pixel are poorly separated. That is, some photons may be absorbed by the wrong layer. Thus, extensive post-processing of the signals is necessary to arrive at the actual values for each of the red, green and blue photodiodes.

In a related design, the vertically stacked photodiodes include vertically stacked color filter segments that incorporate non-silicon materials. These designs improve upon color separation properties of the vertically stacked layers, but also require more complex processing to fabricate.

### BRIEF DESCRIPTION OF THE DRAWINGS

Included in the drawings are the following figures:

FIG. 1A is a diagram of a two pixel group including green and magenta pixels according to an embodiment of the present invention.

FIGS. 1B and 1C are diagrams of the magenta pixel and its equivalent circuit, according to the embodiment shown in FIG. 1A.

FIG. 2 is a graph showing the spectral response characteristics of an embodiment of a magenta filter which may disposed over the magenta pixel shown in FIGS. 1A and 1B.

FIG. 3 is a graph showing the spectral response characteristics of the magenta pixel according to the embodiment shown in FIGS. 1A and 1B.

FIG. 4A is a diagram showing an embodiment of the electrical connections for the green pixel shown in FIGS. 1A and 1B.

FIG. 4B is a structural view of the green pixel according to the embodiment of FIG. 4A.

FIG. 4C is a side structural view of the embodiment of the green pixel shown in FIG. 4B.

FIG. 5A is a diagram showing an embodiment of the electrical connections for the magenta pixel shown in FIGS. 1A and 1B.

FIG. 5B is a structural view of the magenta pixel according to the embodiment of FIG. 5A.

FIG. 5C is a side structural view of the embodiment of the magenta pixel shown in FIG. 5B.

FIG. 6 is a block diagram of an imager incorporating an array of groups of pixels according to the embodiments shown in FIGS. 1A, 1B, 4A, 4B, 4C, 5A, 5B and 5C.

FIG. 7 is a flow chart showing operation steps of the imager shown in FIG. 6 according to an embodiment of the present invention.

### DETAILED DESCRIPTION OF THE INVENTION

The example embodiments described below utilize groups of two pixels to absorb three separate colors of incident light. For example, a single photodiode pixel absorbs green photons and a vertically stacked magenta pixel absorbs red and blue photons. A magenta filter may be disposed over the magenta pixel to block green wavelengths from entering the pixel.

This structure uses two pixels to absorb a full color spectrum. Thus, it improves pixel density 1.5 times relative to four pixel group structures. Further, the pixel provides better spectral separation between the two colors, with less overlap between the spectral responses, than a system that attempts to absorb all blue, green and red photons in one vertically stacked structure. Also, the structure may be used with standard 4T read out techniques. Finally, fabrication requires no special processing relative to standard CMOS imager chips.

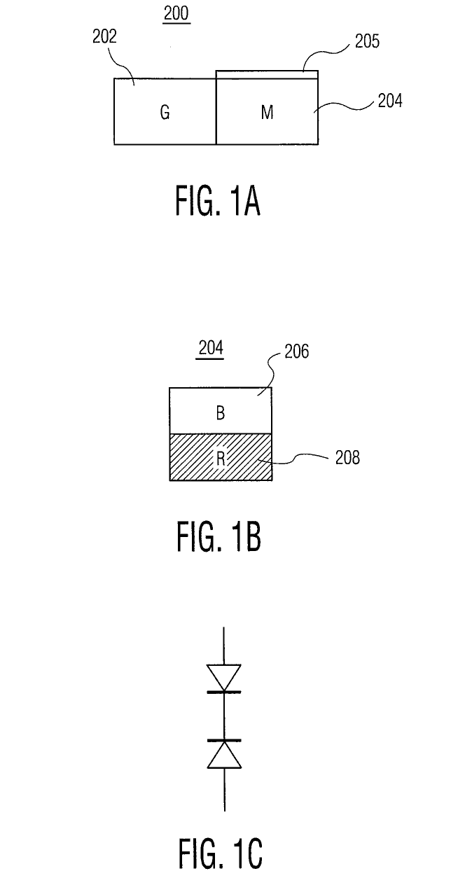

FIG. 1A shows a group 200 of two pixels according to an embodiment of the present invention. As shown, one pixel 202 may measure one color of incident light. In this embodiment, pixel 202 may measure green light (G). Pixel 202 may include a filter designed to transmit green photons and block blue and red photons from entering the pixel. The second pixel 204 may measure two colors of incident light. This pixel (the “magenta pixel”) may measure red and blue photons. Thus, as shown, only two pixels are needed to measure a full color spectrum.

An embodiment of a magenta pixel 204 is shown in FIG. 1B. As shown, pixel 204 is made up of two stacked photodiodes having an equivalent circuit as shown in FIG. 1C. The upper photodiode 206 absorbs blue photons (B) and the lower photodiode 208 absorbs red photons (R). This structure takes advantage of the absorption properties of the semiconductor substrate. That is, blue photons are absorbed at a shallower depth than red photons. Thus, the blue photodiode is disposed in the upper position in the stack (closer to the incident light) and the red photodiode is disposed in the lower position in the stack (farther from the incident light).

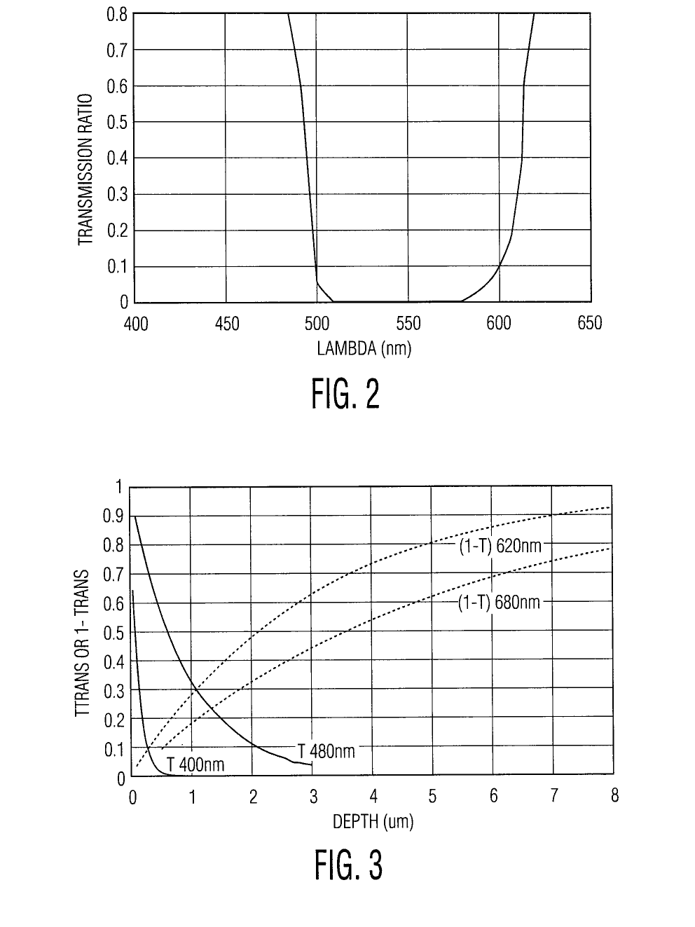

A magenta filter 205 may be disposed over pixel 204 as shown in FIG. 1A. The spectral response characteristics of an embodiment of the magenta filter are shown in FIG. 2. As shown in FIG. 2, the magenta filter transmits wavelengths between 400 nm and 480 nm (corresponding substantially to blue wavelengths) and transmits photons having wavelengths between at least 620 and 680 nm (corresponding substantially to red wavelengths). The magenta filter may transmit a relatively small percentage of photons having wavelengths between approximately 480 and 620 nm (corresponding substantially to green wavelengths). Use of the magenta filter improves color separation properties of the magenta pixel because the green wavelengths are substantially blocked and, therefore, cannot be inadvertently absorbed by the blue and red photodiodes. Use of the magenta filter may be combined with use of an IR blocking filter to block near IR wavelengths of greater than 680 nm.

FIG. 3 shows the spectral response characteristics of the red and blue photodiodes for an embodiment of the magenta pixel. The blue wavelengths are plotted as T (transmission) and the red wavelengths are plotted as 1-T (absorption). As shown, the blue photodiode absorbs photons having wavelengths between 400 and 480 nm and the red photodiode absorbs photons having wavelengths between 620 and 680 nm. This assumes that the magenta filter substantially blocks out photons having wavelengths between 480 and 620 nm. The red photodiode may absorb as much as 30% of the 480 nm photons and the blue photodiode may absorb as much as 30% of the 620 nm photons. The effect of these overlaps may be reduced by post-processing of the pixel signals. One example method of post-processing is described below.

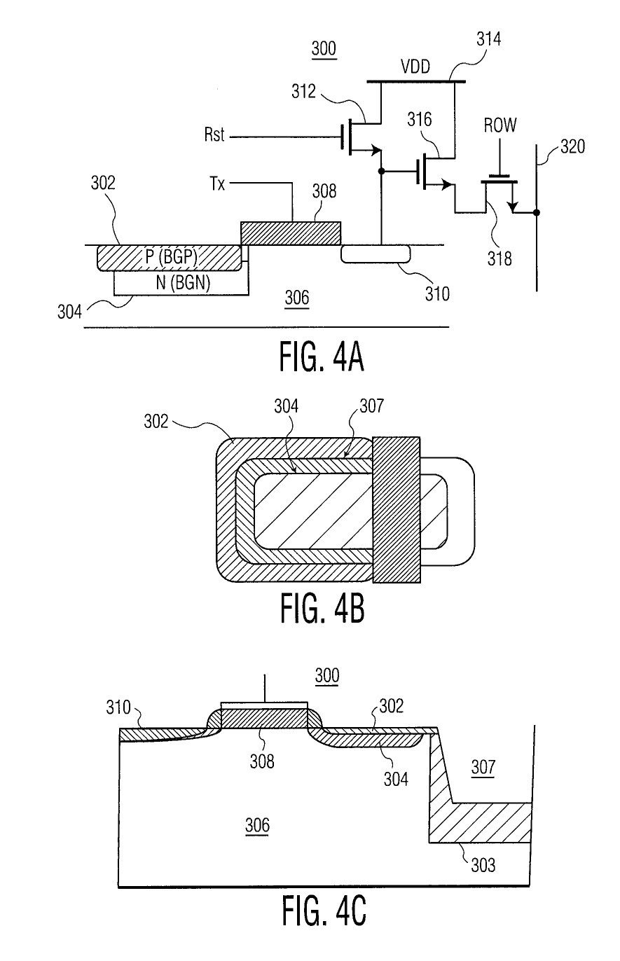

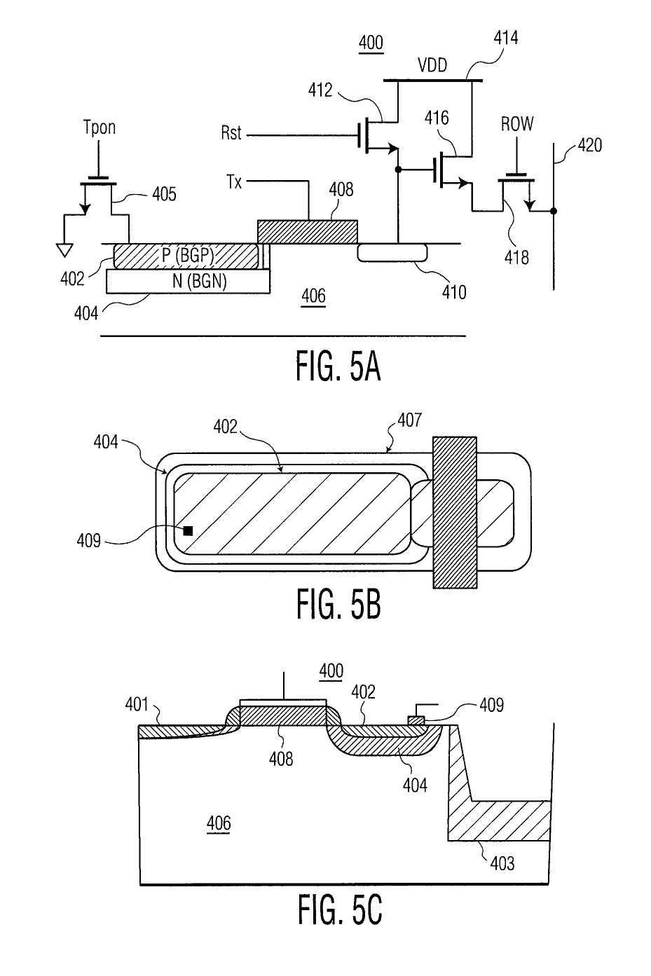

FIGS. 4A and 5A show the electrical connections for an embodiment of a 4T structure for the green and magenta pixels 300 and 400, respectively. As shown, both pixels include a photodiode region, depicted as 302 and 304 for the green pixel and 402 and 404 for the magenta pixel. Both pixels also include a floating diffusion region 310 for the green pixel and 410 for the magenta pixel. The photodiode region and the floating diffusion region, for each pixel, is formed in substrate 306 and 406, respectively. Both pixels further include CMOS circuitry including, for example, a reset transistor (312, 412), a source follower transistor (316, 416), a row select transistor (318, 418), a transfer transistor (308, 408), a column readout line (320, 420) and a pixel supply voltage VDD (314, 414). The magenta pixel 400 also includes a blue photodiode transistor 405.

An example structural layout of the green pixel is shown in FIGS. 4B and 4C and an example structural layout of the magenta pixel is shown in FIGS. 5B and 5C. It should first be noted that the photodiodes in both the green and magenta pixels do not include N or P wells. Instead, the P-type substrate (306, 406) is doped with different doping levels at different depths into the substrate. This is achieved using implants of different types of doping materials. The specific doping materials may be selected according to a TSMC process such as, for example, the TSMC 0.25 μm CIS option or the TSMC 0.18 μm CIS option. The different implants are generally depicted as BGP and BGN in FIGS. 4A-C and 5A-C. The BGP implant and the BGN implant are selected to adjust the threshold of the transfer transistor and set the doping level in the photodiodes to optimize photocurrent. Both pixels include an upper photodiode formed at the junction between the BGP (302, 402) and BGN (304, 404) implants and a lower photodiode formed at the junction between the BGN implant (304, 404) and the P-type substrate (306,406).

As shown in FIGS. 4B and 4C, for the green pixel, the BGP implant 302 overlaps the BGN implant 304. The top photodiode formed at the junction between BGP implant 302 and BGN implant 304 is shorted to P well 303. P well 303, together with oxide isolation region 307, is used to electrically isolate adjacent pixels. The top photodiode may be shorted to P well 303.

As shown in FIGS. 5B and 5C, for the magenta pixel, the BGP implant 402 is completely contained within the BGN implant 404. This is different from the green pixel in that the upper photodiode formed at the junction between the BGP implant 402 and the BGN implant 404 is not shorted to P well 403. This allows the upper photodiode to be separately read using, for example, contact 409 shown in FIG. 5B and transistor 405 shown in FIG. 5A.

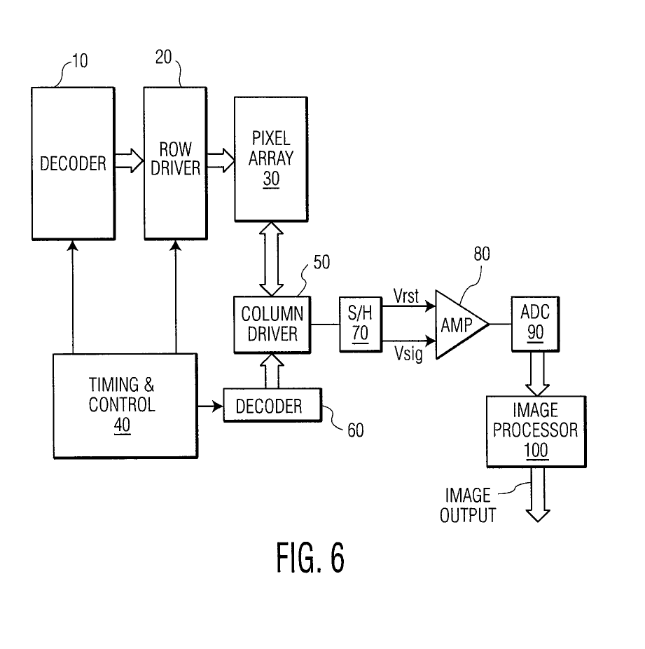

As described above, the two pixel group may be repeated to form an array of lines and columns of the example green and magenta pixels shown in, for example, FIGS. 4A, 4B, 4C, 5A, 5B and 5C. An example array 30, including associated imager processing electronics, is shown in FIG. 6. An operation of the pixel array 30 is described below with reference to FIGS. 4A, 4B, 4C, 5A, 5B, 5C and 6.

For pixel array 30, all pixels in the same row may be sampled, for example, by applying row select signal RS to row select transistors 318 and 418 of the selected row. Alternatively, green pixels in a row may be independently selected by applying RS only to row select transistor 318 and magenta pixels in a row may be independently selected by applying RS only to row select transistor 418. Specific pixels in each column may be selectively output by respective column select lines (e.g.,. lines 320 and 420 shown in FIGS. 4A and 5A, respectively). A plurality of row and column lines (not shown) may be provided for the entire array 30. The row lines may be selectively activated in a sequence by row driver 20 in response to row address decoder 10. Similarly, the column select lines may be selectively activated in a sequence for each row activation by column driver 50 in response to column address decoder 60.

As shown in FIG. 6, the example CMOS imager is operated by timing and control circuit 40, which controls address decoders 10 and 60 to select appropriate row and column lines for pixel readout and controls row and column driver circuitry 20 and 50 to apply driving voltages to the drive transistors (not shown) of the selected row and column lines.

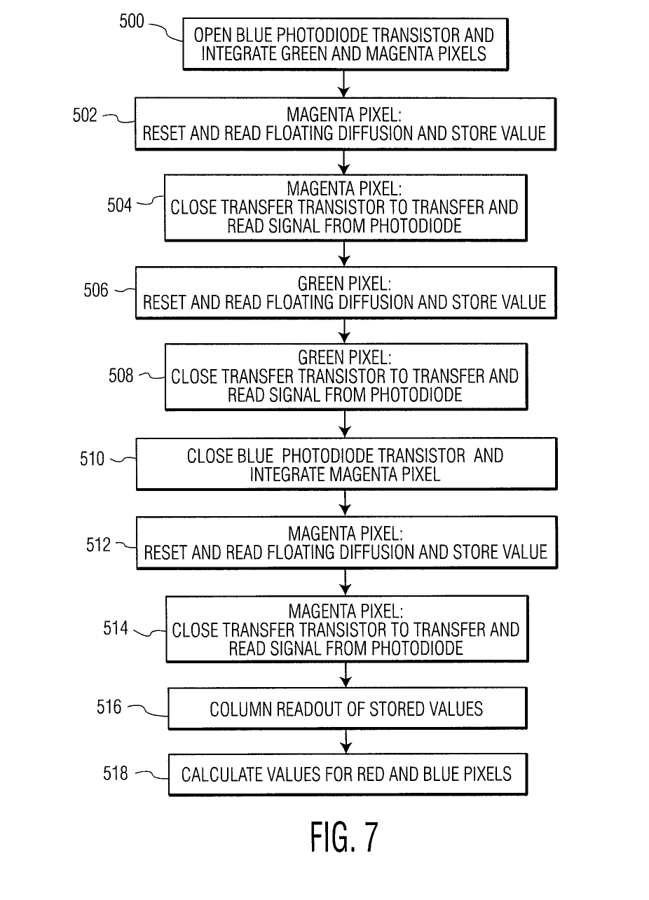

An example sequence for operating the two pixel group described in the above embodiments is shown in the flow chart of FIG. 7. The sequence begins at step 500. At step 500, blue photodiode transistor 405 is opened (Tpon opens or closes transistor 405 by way of its gate). Green and magenta pixels 300 and 400 are integrated over an integration period. At the end of the integration period, floating diffusion 410 of magenta pixel 400 is reset by step 502. The level of floating diffusion 410 is read out through source follower transistor 416 onto column line 420. The level read from the floating diffusion is placed on a first sample and hold capacitor.

At step 504, transfer transistor 408 of the magenta pixel is closed by applying signal Tx to the gate of transistor 408. The level of the lower photodiode is thereby transferred to floating diffusion 410 and read out through source follower transistor 416 onto column line 420. The level read from the lower photodiode is placed on a second sample and hold capacitor. It should be noted that because the blue photodiode transistor is open during this processing, the above-described operation for the magenta pixel is only carried out for lower photodiode 404. However, the values read out and stored are primarily for the red pixel with a small amount of the blue pixel (due to the possibility of some spectral overlap, as described above).

At step 506, floating diffusion 310 of the green pixel is reset. The level of floating diffusion 310 is read out through source follower transistor 316 onto column line 320. The level read from the floating diffusion is placed on a third sample and hold capacitor. At step 508, transfer transistor 308 of the green pixel is closed by applying signal Tx to the gate of transistor 308. The level of the photodiode is thereby transferred to floating diffusion 310 and read out through source follower transistor 316 onto column line 320. The level read from the photodiode is placed on a fourth sample and hold capacitor.

At step 510, blue photodiode transistor 405 is closed by applying signal Tpon to transistor 405. The magenta pixel is integrated again over an integration period. At step 512, floating diffusion 410 of the magenta pixel is reset. The level of floating diffusion 410 is read out through source follower transistor 416 onto column line 420. The level read from the floating diffusion is placed on a fifth sample and hold capacitor.

At step 512, transfer transistor 408 of the magenta pixel is closed by applying signal Tx to the gate of transistor 408. The level of the photodiode is thereby transferred to floating diffusion 410 and read out through source follower transistor 416 onto column line 420. The level read from the photodiode is placed on a sixth sample and hold capacitor. Here, the levels read out and stored are for the sum of the red and blue pixels together.

Referring back to FIG. 6, the first, second, third, fourth, fifth and sixth sample and hold capacitors are represented by S/H block 70. In step 516 of FIG. 7, column readout of the stored levels is carried out for each set of levels (first and second, third and fourth, fifth and sixth). In FIG. 6, the read floating diffusion values are represented by Vrst and the read photodiode values are represented by Vsig. The respective Vrst and Vsig values may be provided to the same differential amplifier 80 or a plurality of different differential amplifiers 80. In either case, Vrst is subtracted from Vsig to obtain an analog differential output signal for each set of signals. The analog output signals are converted into digital signals by analog to digital converter 90 and then transferred to image processor 100 for additional processing. Such processing may include, for example, the post-processing calculations described below. The calculations are performed at step 518 in FIG. 7.

It should be noted that the above sequence is just one example. Depending on the circuitry used, the sequence may be performed differently. For example, all green pixels in a column may be connected to an output line that is used for reading out green pixels and all magenta pixels in a column may be connected to another output line that is used for reading out magenta pixels. In this example, simultaneous integrations and readouts may be performed for the green and magenta pixels.

By way of another example, all green and magenta pixels in a column may be connected to the same readout line. Here, the magenta pixels may be integrated and read. Then, the green pixels may be integrated and read. The possibility of different sequences may, therefore, depend on how the pixels are connected to the column lines going to the sample and hold capacitors.

The post-processing calculations performed at step 518 are for obtaining a desired red value (R) and a desired blue value (B) from the two read out and differentially amplified digital signal values for the magenta pixel described above (represented by U for the signal value from the upper photodiode and L for the combined signal value from the lower photodiode). The U and L signal values may be represented by the following equations:

U=fb*B+fr*R (1)

L=B+R (2)

In equations (1) and (2), fb and fr represent the fraction of blue photons read by the blue photodiode and the fraction of red photons read by the blue photodiode, respectively. From equations (1) and (2), the desired values R and B may be determined according to the following equations:

R=(fb*L−U)/(fb−fr) (3)

B=(U−fr*L)/(fb−fr) (4)

When there is no spectral overlap, fb=1 and fr=0. In this scenario, R=L−U and B=U, as expected. That is, with no spectral overlap, the desired value for red is the combined signal minus the blue signal. Similarly, the desired value for blue is simply the blue signal.

In the example described above, fr=0.3 and fb=0.7. In this scenario, R and B may be determined according to the following equations:

R=1.75L−2.5U (5)

B=2.5U−0.75L (6)

This example may cause some amount of noise increase in both the red and blue signals. It is more likely, however, that the fr and fb values would be closer to the ideal values (no spectral overlap) using a more realistic spectral distribution of an image input into the imager array.

Accordingly, using these calculations, any spectral overlap may be compensated for by selecting appropriate values for fr and fb.

While example embodiments of the invention have been shown and described herein, it will be understood that such embodiments are provided by way of example only. Numerous variations, changes and substitutions will occur to those skilled in the art without departing from the invention. Accordingly, it is intended that the appended claims cover all such variations as fall within the scope of the invention.

What is claimed:

1. A color photo sensing structure, formed in a substrate of a first conductivity type, comprising:
a first doped region of a second conductivity type formed in the substrate, the first doped region formed at a first depth for absorbing a first wavelength of light providing a first color,
a second doped region of the first conductivity type formed in the substrate, the second doped region formed at a second depth for absorbing a second wavelength of light providing a second color, wherein the second doped region is disposed above the first doped region, resulting in the second depth being less than the first depth, and
controller for sequentially providing
a first photocurrent value of the first doped region, and
next, a second photocurrent value of both the first and second doped regions.

2. The color photo sensing structure of claim 1, wherein
the first color is red,
the second color is blue,
the first photocurrent value is substantially from red light absorbed by the first doped region, and
the second photocurrent value is substantially from a sum of red light and blue light absorbed, respectively, by the first doped region and the second doped region.

3. The color photo sensing structure of claim 1, wherein
the second doped region circumferentially surrounds the first doped region.

4. The color photo sensing structure of claim 1, wherein
the controller includes a transistor having a drain connected to the second doped region, and a source connected to a ground reference, and
the controller configured to place the first doped region at the ground reference when the transistor is ON,
wherein the first photocurrent value is provided when the transistor is OFF and the second photocurrent value is provided when the transistor is ON.

5. The color photo sensing structure of claim 1 including
a separate region formed in the substrate, laterally displaced from the first and second doped regions for absorbing a third wavelength of light providing a third color.

6. The color photo sensing structure of claim 5, wherein
the first color is red,
the second color is blue, and
the third color is green.

7. The color photo sensing structure of claim 5, wherein
the first doped region and the second doped region are a portion of a magenta pixel,
the separate region is a portion of a green pixel, and
the magenta and green pixels are part of a pattern of magenta and green pixels.

8. The color photo sensing structure of claim 5, wherein
the separate region is formed of a third doped region of the second conductivity type, and a fourth doped region of the first conductivity type, and
the fourth doped region overlaps the third doped region.

9. The color photo sensing structure of claim 8 including
a p-well for forming a shallow trench isolation region in the substrate, wherein
a junction between the third doped region and the fourth doped region is shorted to the p-well.

10. A color photo sensor structure formed in a silicon substrate of p-type conductivity for separating light of blue, green and red wavelengths, the structure comprising:
a first region of n-type conductivity formed in the substrate for absorbing light of red wavelength,
a second region of p-type conductivity formed in the substrate, stacked above the first region, for absorbing light of blue wavelength, and
a third region formed of both p-type conductivity and n-type conductivity formed in the substrate, disposed laterally to both the first and second regions, for absorbing light of green wavelength.

11. The color photo sensor structure of claim 10, further comprising:
a first transfer gate connected between the first region and a first photosensitive region, the first transfer gate configured to transfer a first signal from the first region to the photosensitive region for readout of the signal;
a second transfer gate connected between the third region and a second photosensitive region, the second transfer gate configured to transfer a second signal from the third region to the second photosensitive region for readout of the signal;
a transistor connected to the second region configured such that when the transistor and the first transfer gate are closed, a third signal is transferred from the first region and the second region to the first photosensitive region for readout of the third signal.

12. The color photo sensor of claim 10, further comprising:
a p-well for forming a shallow trench isolation region in the substrate,
wherein a junction between the p-type conductivity and the n-type conductivity of the third region is shorted to the p-well.

13. The color photo sensing structure of claim 1 including
a magenta filter disposed above the second doped region.

14. The color photo sensing structure of claim 13, wherein
the magenta filter is configured to filter wavelengths between 400 nm and 480 nm.

15. The color photo sensing structure of claim 13, wherein
the magenta filter includes an IR blocking filter for preventing wavelengths greater than 680 nm from entering the structure.

16. An imaging array comprising:
a matrix of rows and columns of color pixels formed in a silicon substrate having a first conductivity type,
the matrix arranged in a pattern of alternating magenta and green pixels
wherein the magenta pixel includes
a first doped region of a second conductivity type formed in the substrate, the first doped region formed at a first depth for absorbing a wavelength of light providing a red color, and
a second doped region of the first conductivity type formed in the substrate, the second doped region formed at a second depth for absorbing a wavelength of light providing a blue color, wherein the second doped region is disposed above the first doped region, and
the green pixel includes a third doped region of the second conductivity type, and a fourth doped region of the first conductivity type for absorbing a wavelength of light providing a green color.

17. The imaging device of claim 16 including
a controller for sequentially providing
a first photocurrent value of the first doped region, and
next, a second photocurrent value of both the first and second doped regions.

18. The imaging device of claim 17,
wherein the controller is further for providing a third photocurrent value of the third doped region and the fourth doped region.

19. The imaging device of claim 18, further comprising:
a first sample and hold capacitor for temporarily storing the first photocurrent value;
a second sample and hold capacitor for temporarily storing the second photocurrent value; and
a third sample and hold capacitor for temporarily storing the third photocurrent value.

20. A method of providing a sequence of output signals from a matrix of pixels having a color pattern, the method comprising the steps of:
providing a first output signal from a magenta colored pixel, wherein the magenta colored pixel is formed by stacking a second doped region on top of a first doped region in a substrate, and the first output signal results primarily from photons absorbed in the first doped region,
providing a second output signal from the magenta colored pixel, wherein the second output signal results from photons absorbed in both the first and second doped regions, and
providing a third output signal from a green colored pixel, wherein the green colored pixel includes third and fourth doped regions in the substrate, and the third and fourth doped regions are disposed laterally from the stacked first and second doped regions.

21. The method of claim 20 wherein
providing the first output signal includes providing an intensity of absorbed photons of a red wavelength,
providing the second output signal includes providing an intensity of absorbed photons of both red and blue wavelengths, and
providing the third output signal includes providing an intensity of absorbed photons of a green wavelength.

22. The method of claim 21,
wherein the first output signal includes providing an intensity of photons of a red wavelength absorbed by the first doped region and an intensity of photons of a blue wavelength inadvertently absorbed by the first doped region,
the method further comprising the step of:
determining a desired red value and a desired blue value using the first output signal, the second output signal, a percentage of photons of the red wavelength absorbed by the first doped region and a percentage of photons of the blue wavelength absorbed by the first doped region.

23. A method of operating a color photo sensor structure, the color photo sensor structure comprising a first pixel including a first photodiode and a second pixel including a second photodiode and a third photodiode vertically stacked, the method comprising the steps of:
exposing the first pixel and the second pixel to an incident light for a first predetermined period of time;
providing a first output signal from the first photodiode corresponding to an intensity of photons absorbed by the first photodiode;
providing a second output signal from the third photodiode corresponding to an intensity of photons absorbed by the third photodiode;
exposing the second pixel to the incident light for a second predetermined period of time; and
providing a third output signal from the first photodiode and the second photodiode corresponding to an intensity of photons absorbed by the first and second photodiodes.

24. The method of operating the color photo sensor structure of claim 23,
wherein the steps of providing the first output signal and providing the second output signal take place simultaneously.

25. The method of operating the color photo sensor structure of claim 24, further comprising the steps of:
separately storing the first output signal, the second output signal and the third output signal in a first sample and hold capacitor, a second sample and hold capacitor and a third sample and hold capacitor, respectively.
